(19) United States
(12) Patent Application Publication
(10) Pub. No.: US 2024/0175617 A1
(43) Pub. Date: May 30, 2024

(54) POWER CONVERTER AND REFRIGERATION CYCLE APPARATUS

(71) Applicant: Mitsubishi Electric Corporation, Tokyo (JP)

(72) Inventor: Kenji IWAZAKI, Tokyo (JP)

(21) Appl. No.: 18/574,635

(22) PCT Filed: Sep. 14, 2021
(86) PCT No.: PCT/JP2021/033715

§ 371 Date: Dec. 27, 2023

(51) Int. Cl. F25B 49/02; H02K 11/33; H03H 1/00

(52) U.S. Cl. CPC F25B 49/025; H02K 11/33; H03H 1/0007; F25B 2500/12; F25B 2600/021; H02K 2211/03

(57) ABSTRACT

A power converter includes: a power conversion module configured to convert a voltage and a frequency of power that is supplied from a power supply through a power wire, and to supply to a load, power having a voltage and a frequency that are obtained by conversion; and an active noise canceller configured to detect noise that flows through the power wire, and to output a noise canceling signal that attenuates the noise to the power wire. The active noise canceller includes a first substrate on which a strong electric circuit configured to detect the noise is mounted, and a second substrate on which a light electric circuit configured to produce the noise canceling signal is mounted.

### TECHNICAL FIELD

The present disclosure relates to a power converter including a filter configured to attenuate noise that flows out from a converter or an inverter, and also relates to a refrigeration cycle apparatus provided with the power converter.

### BACKGROUND ART

In the past, an air-conditioning apparatus has been known which employs, for the purpose of extending an operating range and improving the efficiency, an inverter configured to perform a variable-voltage variable-frequency operation by switching operation of power conversion elements, and an active converter configured to control a DC voltage that is supplied to the inverter and to control a current that flows out to a power supply. Patent Literature 1 discloses a power converter provided with an active noise canceller including a common-mode noise detection module and an active noise filter configured to compensate for the noise.

### CITATION LIST

### Patent Literature

Patent Literature 1: Japanese Unexamined Patent Application Publication No. 2018-191443

### SUMMARY OF INVENTION

### Technical Problem

In general, in many active noise cancellers, in a light electric circuit including semiconductor elements, there is a higher risk that a failure may occur due to lightning surge, static electricity, heat, or other factors than in a strong electric circuit. Therefore, when a failure occurs in the active noise canceller, in many cases, the light electric circuit is replaced by a new one as a repair. In the replacement of the light electric circuit, it is necessary to shut off a power supply of a device including a power converter. Thus, when the active noise canceller is repaired, the serviceability of the device is reduced.

The present disclosure is applied to solve the above problem, and relates to a power converter that is included in a device or an apparatus whose serviceability is improved at the time of repairing an active noise canceller, and to provide a refrigeration cycle apparatus.

### Solution to Problem

A power converter according to one embodiment of the present disclosure includes: a power conversion module configured to convert a voltage and a frequency of power that is supplied from a power supply through a power wire, and to supply to a load, power having a voltage and a frequency that are obtained by conversion; and an active noise canceller configured to detect noise that flows through the power wire, and to output a noise canceling signal that attenuates the noise to the power wire. The active noise canceller includes a first substrate on which a strong electric circuit configured to detect the noise is mounted, and a second substrate on which a light electric circuit configured to produce the noise canceling signal is mounted.

### Advantageous Effects of Invention

In the power converter and the refrigeration cycle apparatus according to the embodiment of the present disclosure, even when replacement work is performed on the strong electric circuit in which there is a high risk that a failure may occur, it suffices that only the second substrate is replaced by a new one. Thus, it is possible to perform the replacement work without stopping operation of an apparatus to which the active noise canceller is attached, such as an air-conditioning apparatus. In the manner as described above, in the power converter in the embodiment of the present disclosure, it is possible to improve the serviceability of the device including the power converter at the time of repairing the active noise canceller.

### BRIEF DESCRIPTION OF DRAWINGS

FIG. 1 is a circuit diagram illustrating an air-conditioning apparatus according to Embodiment 1.

FIG. 2 is a circuit diagram illustrating a power converter according to Embodiment 1.

FIG. 3 is a circuit diagram illustrating a second substrate in the power converter according to Embodiment 1.

FIG. 4 is a perspective view illustrating an active noise canceller according to Embodiment 1.

FIG. 5 is a perspective view illustrating a first substrate and the second substrate of the active noise canceller according to Embodiment 1.

FIG. 6 is a flowchart illustrating operation of a failure detection circuit according to Embodiment 1.

FIG. 7 is a flowchart illustrating operation of a controller according to Embodiment 1 at the time of detecting a failure.

FIG. 8 is a circuit diagram illustrating a power converter according to Embodiment 2.

FIG. 9 is a circuit diagram illustrating a second substrate in the power converter according to Embodiment 2.

FIG. 10 is a flowchart illustrating operation of a failure detection circuit according to Embodiment 2.

FIG. 11 is a flowchart illustrating operation of an external inspection device according to Embodiment 2.

FIG. 12 is a flowchart illustrating operation of a controller according to Embodiment 2 at the time of detecting a failure.

FIG. 13 is a perspective view illustrating an active noise canceller according to Embodiment 3.

FIG. 14 is a perspective view illustrating an active noise canceller according to Embodiment 4.

### DESCRIPTION OF EMBODIMENTS

### Embodiment 1

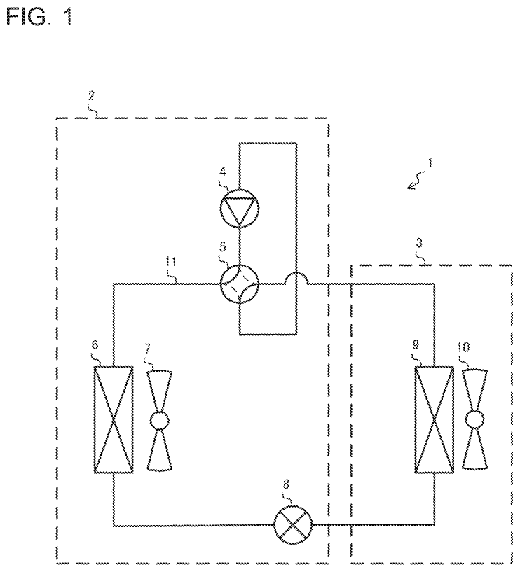

Embodiments of a power converter 100 according to the present disclosure and an air-conditioning apparatus 1 including the power converter 100 will be described with reference to the drawings. The air-conditioning apparatus 1 as illustrated in FIG. 1 is an example of a refrigeration cycle apparatus according to the present disclosure. The present disclosure is not limited to the embodiments described below, and various modifications can be made without departing from the scope of the present disclosure. In addition, the present disclosure encompasses all combinations of configurations that can be combined among the configurations described below regarding the embodiments and modifications thereof. In each of figures in the drawings, components that are the same as or equivalent to those in a previous figure or previous figures are denoted by the same reference signs. The same is true of the entire text of the specification. It should be noted that in each of the figures, a relative relationship or relative relationships between components may be in, for example, size or shape, different from actual ones. In the following, an electrical connection or a magnetic connection may be simply referred to as “connection.”

FIG. 1 is a circuit diagram illustrating the air-conditioning apparatus 1 according to Embodiment 1. As illustrated in FIG. 1, the air-conditioning apparatus 1 includes an outdoor unit 2 and an indoor unit 3. The outdoor unit 2 and the indoor unit 3 are connected by a refrigerant pipe 11. In the outdoor unit 2, a compressor 4, a four-way valve 5, an outdoor heat exchanger 6, an outdoor fan 7, and an expansion valve 8 are provided. In contrast, in the indoor unit 3, an indoor heat exchanger 9 and an indoor fan 10 are provided. The compressor 4 sucks refrigerant that flows in a refrigerant pipe 11. The compressor 4 compresses the sucked refrigerant, and discharges the compressed refrigerant to the refrigerant pipe 11. The compressor 4 is, for example, an inverter compressor. The refrigerant discharged from the compressor 4 flows into the outdoor heat exchanger 6 in the outdoor unit 2 or flows into the indoor heat exchanger 9 in the indoor unit 3. The outdoor heat exchanger 6 and the indoor heat exchanger 9 cause heat exchange to be performed between air and refrigerant that flows in the outdoor heat exchanger 6 and the indoor heat exchanger 9, respectively. The outdoor heat exchanger 6 and the indoor heat exchanger 9 are, for example, fin-and-tube heat exchangers. The outdoor fan 7 sends air to the outdoor heat exchanger 6. The indoor fan 10 sends air to the indoor heat exchanger 9. The state of the four-way valve 5 is switched between a state of the four-way valve 5 for a cooling operation to cool air close to the indoor unit 3 and that for a heating operation to heat air close to the indoor unit 3.

Specifically, in the cooling operation, the state of the four-way valve 5 is switched to a state indicated by solid lines, whereby the refrigerant discharged from the compressor 4 flows into the outdoor heat exchanger 6 in the outdoor unit 2. At this time, the outdoor heat exchanger 6 in the outdoor unit 2 serves as a condenser, and the indoor heat exchanger 9 in the indoor unit 3 serves as an evaporator. In contrast, in the heating operation, the state of the four-way valve 5 is switched to a state indicated by dotted lines, whereby the refrigerant discharged from the compressor 4 flows into the indoor heat exchanger 9. At this time, the outdoor heat exchanger 6 in the outdoor unit 2 serves as an evaporator, and the indoor heat exchanger 9 in the indoor unit 3 serves as a condenser. The expansion valve 8 is a pressure-reducing device that reduces the pressure of the refrigerant, and is, for example, an electronic expansion valve. The expansion valve 8 is provided between the outdoor heat exchanger 6 in the outdoor unit 2 and the indoor heat exchanger 9 in the indoor unit 3. The compressor 4, the four-way valve 5, the outdoor heat exchanger 6, the expansion valve 8, and the indoor heat exchanger 9 are connected by refrigerant pipes 11, whereby a refrigerant circuit is provided.

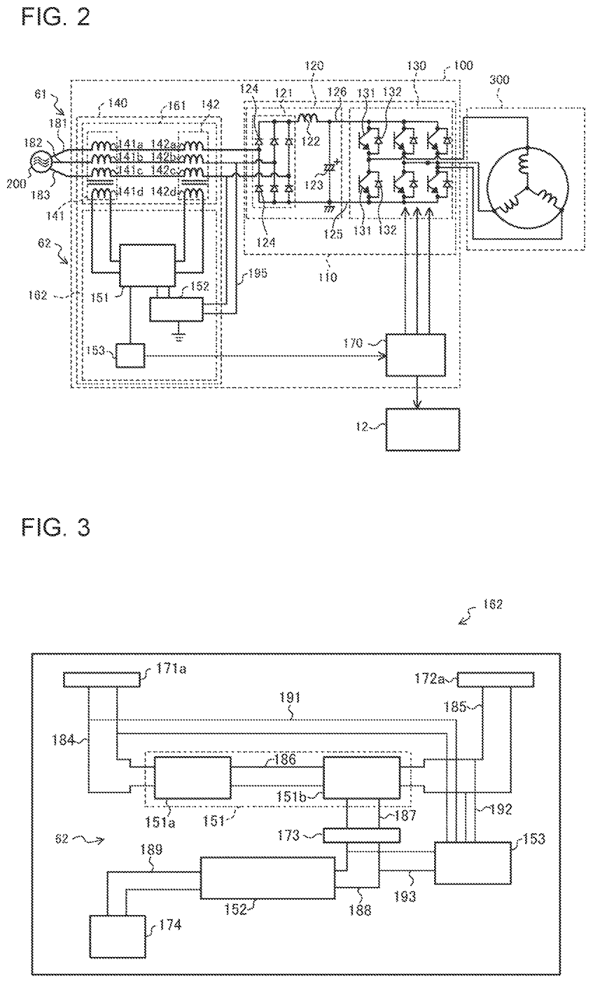

FIG. 2 is a circuit diagram illustrating the power converter 100 according to Embodiment 1. As illustrated in FIG. 1, the power converter 100 according to Embodiment 1 includes a power conversion module 110, an active noise canceller 140, and a controller 170. In the following, the active noise canceller may be sometimes referred to as “ANC.” To the power converter 100, an AC power supply 200 and a motor 300 are connected as a power supply and a load, respectively. The AC power supply 200 is, for example, a three-phase commercial power supply having a U-phase, a V-phase, and a W-phase. The AC power supply 200 is connected to the power converter 100 through a power terminal block (not illustrated). The motor 300 is, for example, a three-phase permanent magnet synchronous motor having a U-phase, a V-phase, and a W-phase. The power converter 100 and the motor 300 are provided in, for example, the compressor 4 of the air-conditioning apparatus 1. The motor 300 may be used as a fan motor for the outdoor fan 7 and the indoor fan 10. In that case, the power converter 100 may be provided in an inverter device that drives the outdoor fan 7 and the indoor fan 10.

The power conversion module 110 converts a voltage and a frequency of AC power supplied from the AC power supply 200, and supplies to the motor 300, power having a voltage and a frequency that are obtained by the above conversion. The power conversion module 110 includes a converter 120 and an inverter 130. The converter 120 includes a rectifier circuit 121, a DC reactor 122, and a smoothing capacitor 123. The converter 120 further includes a booster circuit (not illustrated). The rectifier circuit 121 rectifies and converts an AC voltage from the AC power supply 200 to a DC voltage. On an output side of the rectifier circuit 121, the smoothing capacitor 123 is connected in parallel with the rectifier circuit 121 through the DC reactor 122. The smoothing capacitor 123 smooths the DC voltage that is input thereto from the rectifier circuit 121 through the DC reactor 122. The booster circuit is connected to the output side of the rectifier circuit 121 to perform a boost switching operation.

The rectifier circuit 121 is, for example, a full-bridge circuit including six rectifier diodes 124. To be more specific, two of the rectifier diodes 124 are connected in series, forming a series body. Three series bodies each formed in such a manner are prepared, and then connected in parallel with each other, thereby forming the full-bridge circuit. Furthermore, middle points of the three series bodies are connected to the AC power supply 200 by three power wires 181, 182, and 183 that are associated with respective phases of the AC power supply 200. It should be noted that the rectifier circuit 121 may employ switching elements such as transistors, instead of the rectifier diodes 124. Output ends of the rectifier circuit 121 are connected to respective bus-bars, that is, a positive bus-bar 125 and a negative bus-bar 126.

The inverter 130 is, for example, a full-bridge circuit including six semiconductor switches 131. Each of the semiconductor switches 131 is a switching element, such as an insulated gate bipolar transistor (IGBT), a metal-oxide-semiconductor field effect transistor (MOSFET), or a high electron mobility transistor (HEMT). The inverter 130 switches the state of each of the semiconductor switches 131 between on and off-states to control a passage for a current that flows to the motor 300 and drive the motor 300. In the inverter 130, at least associated two semiconductor switches 131 for each of the phases are connected in series, forming a series body. One of ends of the series body is connected to a power-supply potential side (high-potential side) and the other end is connected to a reference potential side (low-potential side). Furthermore, middle points of three series bodies each formed in the above manner are connected to the motor 300.

Referring to FIG. 2, the inverter 130 is connected to the positive bus-bar 125 and the negative bus-bar 126 that are output ends of the converter 120. The inverter 130 converts the DC voltage rectified by the rectifier circuit 121 in the converter 120 to an AC voltage, and outputs the AC voltage to the motor 300. Because of the operation of the inverter 130, it is possible to change the voltage value and frequency of AC power to be supplied to the motor 300.

Freewheeling diodes 132 are connected in inverse parallel with the respective semiconductor switches 131. The semiconductor switches 131 each perform on-off operation independently from each other in response to a drive switch signal output from the controller 170. Through the on-off operation, a DC voltage is converted to an AC voltage.

The ANC 140 is an active filter that detects common-mode noise that flows out from the converter 120 or the inverter 130 and then flows to the power wires 181, 182, and 183, and attenuates and reduces the detected noise. The ANC 140 includes a detection coil 141, an injection coil 142, a noise reduction circuit 151, a control power circuit 152, and a failure detection circuit 153. The detection coil 141 and the injection coil 142 are included in a strong electric circuit 61 in the ANC 140. The strong electric circuit 61 is configured mainly to detect common-mode noise. Components of the strong electric circuit 61 are devices that use a voltage close to the power-supply voltage. The strong electric circuit 61 uses a power-supply voltage of, for example, 200 to 400 V. The noise reduction circuit 151, the control power circuit 152, and the failure detection circuit 153 are included in a light electric circuit 62 in the ANC 140. The light electric circuit 62 is configured mainly to produce a noise cancelling signal that reduces the common-mode noise. Components of the light electric circuit 62 are devices that use a voltage obtained by stepping down the power-supply voltage. The components of the light electric circuit 62 use a voltage of around 10 V, which is sufficiently low, as compared with the voltage that is used by the components of the strong electric circuit 61. The ANC 140 includes separate substrates that are a first substrate 161 on which the strong electric circuit 61 is mounted and a second substrate 162 on which the light electric circuit 62 is mounted. On the first substrate 161, the light electric circuit 62 is not mounted.

The detection coil 141 and the injection coil 142 are inserted in this order from one side of the ANC 140 that is close to the AC power supply 200, such that the detection coil 141 and the injection coil 142 are connected in series with the power wires 181, 182, and 183. That is, the detection coil 141 is connected to the AC power supply 200, and the injection coil 142 is connected to the converter 120. The detection coil 141 and the injection coil 142 have a withstand voltage higher than the voltage of the AC power supply 200.

The detection coil 141 includes coils 141a, 141b, and 141c that are respectively connected in series to the power wires 181, 182, and 183 for the respective phases. That is, each of the coils 141a, 141b, and 141c is a conductive wire that forms part of an associated one of the power wires 181, 182, and 183. The coils 141a, 141b, and 141c are, for example, wound around a toroidal core. The toroidal core is annular and made of magnetic material such as ferrite. The detection coil 141 further includes a coil 141d. For example, the coil 141d is wound around the toroidal core such that the coil 141d is adjacent to the coils 141a, 141b, and 141c, and is provided such that the coil 141d is magnetically coupled with the coils 141a, 141b, and 141c.

The injection coil 142 includes coils 142a, 142b, and 142c that are respectively connected in series to the power wires 181, 182, and 183 for the respective phases. That is, each of the coils 142a, 142b, and 142c is a conductive wire that forms part of an associated one of the power wires 181, 182, and 183. The coils 142a, 142b, and 142c are, for example, wound around a toroidal core. The injection coil 142 further includes a coil 142d. For example, the coil 142d is wound around the toroidal core such that the coil 142d is adjacent to the coils 142a, 142b, and 142c, and is provided such that the coil 142d is magnetically coupled with the coils 142a, 142b, and 142c.

Operation of the ANC 140 will be described below. When a common-mode noise current flows to the coils 141a, 141b, and 141c, a current that is proportional to the common-mode noise current, that is, a noise signal, is induced in the coil 141d through the toroidal core. Based on the noise signal which flows in the detection coil 141, the noise reduction circuit 151 sets a noise cancelling signal that attenuates or cancels out the noise signal, and causes the set noise canceling signal to flow to the coil 142d. By the noise canceling signal which flows in the coil 142d, a noise cancelling signal is induced in the coils 142a, 142b, and 142c of the injection coil 142, which are magnetically coupled with the coil 142d. The noise canceling signal flows to the power wires 181, 182, and 183 through the coils 142a, 142b, and 142c of the injection coil 142. That is, a current induced by the injection coil 142 is superimposed on the current which flows through the power wires 181, 182, and 183. At this time, the noise canceling signal and the noise signal which flows through the power wires 181, 182, and 183 cancel each other out, thereby reducing the common mode noise.

It should be noted that referring to FIG. 2, noise detection and noise injection are carried out using coils, however, any device other than the coils may be used for the noise detection and noise injection, as long as it is possible to detect and inject a noise current that flows through the power wires 181, 182, and 183. For example, one or both of noise detection and noise injection may be carried out by using a capacitor. Furthermore, on the first substrate 161, auxiliary noise suppression devices, such as an X-capacitor, a Y-capacitor, and a normal-mode coil may be mounted as components that accessorily reduce noise. In this case, the X-capacitor and the Y-capacitor have a withstand voltage higher than the voltage of the AC power supply 200. It should be noted that a plurality of X-capacitors and a plurality of Y-capacitors may be provided. In this case, the withstand voltage of the X-capacitors and the Y-capacitors may be the withstand voltage of the combination of the plurality of X-capacitors and the plurality of Y-capacitors. Also, it should be noted that the above capacitors or the normal-mode coil which are provided in addition to or instead of the coils are also included in the strong electric circuit 61.

It should be noted that the normal-mode noise that flows through the power wires 181, 182, and 183 is reduced by a leakage inductance of the detection coil 141 and the injection coil 142. In the case where the X-capacitor is mounted, the normal-mode noise is also reduced by the X-capacitor.

FIG. 3 is a circuit diagram illustrating the second substrate 162 of the power converter 100 according to Embodiment 1. As illustrated in FIG. 3, on the second substrate 162, the noise reduction circuit 151, the control power circuit 152, and the failure detection circuit 153 are mounted. It should be noted that although referring to FIG. 3, parallel wires are connected between circuits or between connectors such that between any two of the circuits or the connectors, associated two of the parallel wires are connected, only one of these two parallel wires will be denoted by a reference sign, and a description concerning the other will be omitted. The noise reduction circuit 151 is connected to a connector 171a by a wire 184. The connector 171a is connected to a connector 171b (see FIG. 5) on the first substrate 161. Thus, the noise reduction circuit 151 can receive a noise signal from the detection coil 141 on the first substrate 161. The noise reduction circuit 151 is connected to a connector 172a by a wire 185. The connector 172a is connected to a connector 172b (see FIG. 5) on the first substrate 161. Thus, the noise reduction circuit 151 can transmit a noise canceling signal to the injection coil 142 on the first substrate 161. The noise reduction circuit 151 further includes a high-pass filter 151a and an amplifier circuit 151b. The high-pass filter 151a and the amplifier circuit 151b are connected by a wire 186.

The high-pass filter 151a uses a specific frequency as a threshold for a noise signal detected by the detection coil 141 to allow only a frequency component of the noise signal that is higher than the threshold to pass through the high-pass filter 151a. The amplifier circuit 151b amplifies a current whose phase is opposite to that of the noise signal having passed through the high-pass filter 151a, thereby producing a noise cancelling signal, and transmits the noise canceling signal to the injection coil 142. It should be noted that the configuration of the noise reduction circuit 151 is not limited to the above configuration. For example, the noise reduction circuit 151 may further include, for example, a buffer circuit and a low-frequency cancel circuit.

The amplifier circuit 151b is a semiconductor circuit including at least an operational amplifier and a transistor. The high-pass filter 151a includes at least a resistor and a capacitor. The amplifier circuit 151b may further include, for example, a resistor and a capacitor that are included in the circuit. It should be noted that the resistor or capacitor provided in addition to or instead of the above components are also included in the light electric circuit 62. These components of the semiconductor circuit have lower durability than that of the components of the strong electric circuit 61. The operational amplifier and the transistor have a withstand voltage lower than the voltage of the AC power supply 200.

The control power circuit 152 is connected to the amplifier circuit 151b in the noise reduction circuit 151 through a connector 173. The amplifier circuit 151b and the connector 173 are connected by a wire 187. The connector 173 and the control power circuit 152 are connected by a wire 188. The control power circuit 152 is connected to the power wires 182 and 183 on the first substrate 161 through a connector 174 connected to the control power circuit 152 by a wire 189 (see FIG. 2). Specifically, although it is not illustrated, a wire for connection to a power supply, a connector, a fuse, and other components are mounted on the first substrate 161. The connector on the first substrate 161 and the connector 174 on the second substrate 162 are connected by a power wire 195 (see FIG. 2), and the control power circuit 152 receives an alternating current that flows through a region located upstream of the converter 120, as a power supply. The control power circuit 152 supplies the received power to the amplifier circuit 151b. An output voltage of the control power circuit 152 is lower than the withstand voltage of the operational amplifier and the transistor in the amplifier circuit 151b. It should be noted that the control power circuit 152 may use a direct current that flows through a region located downstream of the converter 120, as a power supply. Also, the control power circuit 152 may supply power through a system other than the above system.

The failure detection circuit 153 detects a failure in the ANC 140 based on the value of a current or a voltage that is obtained from a noise signal and a noise canceling signal, or based on the values of a voltage and a current that are input to the amplifier circuit 151b. When a failure occurs in the ANC 140, a noise cancel operation is not performed, and noise thus leaks to the power wires 181, 182, and 183. It should be noted that in the following, each of the value of the current or voltage that is obtained from the noise signal and the noise canceling signal and the values of the voltage and current that are input to the amplifier circuit 151b may be referred to as a “monitoring value.” After detecting a failure at the ANC 140, the failure detection circuit 153 measures a change in the monitoring value that is made by a change in the operating condition of the air-conditioning apparatus 1, and detects whether noise leakage still continues. Furthermore, when the failure detection circuit 153 detects a failure in the ANC 140, and noise leakage still continues, then the failure detection circuit 153 transmits to the controller 170, a failure signal indicating that a failure occurs in the ANC 140.

Specifically, the failure detection circuit 153 is connected by a wire 191, to the wire 184 extending between the connector 171a and the high-pass filter 151a. The failure detection circuit 153 is connected by a wire 192, to the wire 185 extending between the amplifier circuit 151b and the connector 172a. The failure detection circuit 153 acquires a noise signal that passes through the wire 184 and is input to the high-pass filter 151a, and acquires a noise canceling signal that is output from the amplifier circuit 151b and passes through the wire 185. When the value of a current or a voltage that is obtained from the acquired noise signal and noise canceling signal exceeds a threshold set in advance, the failure detection circuit 153 determines that an abnormality occurs in the noise reduction circuit 151, such as short circuit, circuit opening, or oscillation, and thus detects a failure.

The failure detection circuit 153 is connected by a wire 193, to the wire 188 extending between the connector 173 and the control power circuit 152. The failure detection circuit 153 measures the values of a voltage and a current that are input from the control power circuit 152 to the amplifier circuit 151b through the wire 193. When the measured values of the voltage and current exceed a threshold set in advance, the failure detection circuit 153 determines that an abnormality, such as short circuit, circuit opening, or oscillation, occurs in the control power circuit 152, and thus detects a failure.

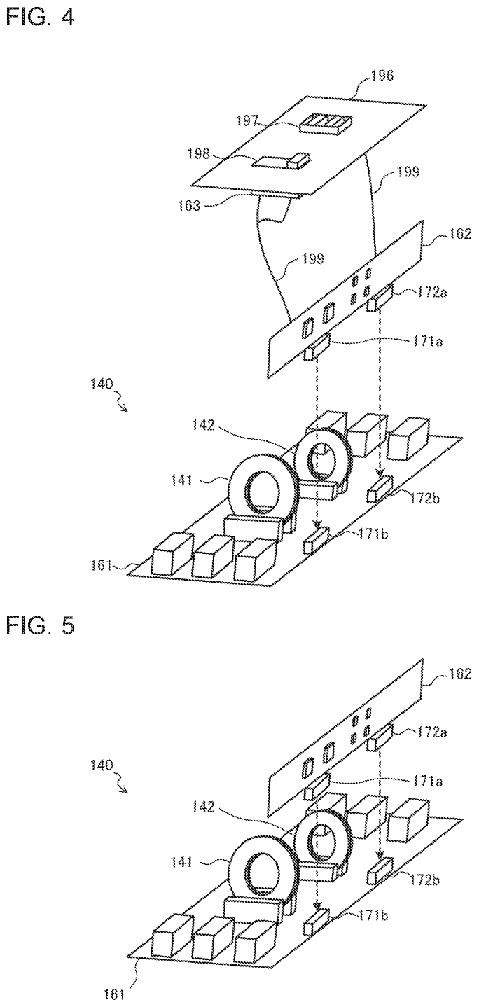

FIG. 4 is a perspective view illustrating the active noise canceller 140C according to Embodiment 1. The ANC 140 and a power terminal block are accommodated in an electrical component box 196. It should be noted that FIG. 4 illustrates only part of an upper surface of the electrical component box 196. Also, FIG. 4 illustrates a state of the ANC 140 in which the first substrate 161 and the second substrate 162 have not yet been assembled together, that is, the state prior to assemblage of the first substrate 161 and the second substrate 162. In the electrical component box 196, the first substrate 161 and the second substrate 162 are provided close to the power terminal block and flush with the power terminal block. Thus, a worker can easily repair the ANC 140 and perform other work, and the maintainability can thus be improved. As illustrated in FIG. 4, an inspection substrate 163 is provided on an inner surface of an upper portion of the electrical component box 196. The inspection substrate 163 and the second substrate 162 are electrically and mechanically connected by leads 197 and a connector (not illustrated). On the inspection substrate 163, an inspection LED 198 and an inspection switch 199 are mounted. The inspection LED 198 is configured to light, go out, or flash on the surface of the electrical component box 19 to display whether a failure occurs in the ANC 140 or not. As a result, it is possible to determine whether a failure occurs in the ANC 140 or not, from the outside of the electrical component box 196. It is possible to switch the state of the inspection switch 199 between the on-state and the off-state by moving a knob provided on the surface of the electrical component box 196. The inspection switch 199 is configured to allow or inhibit the power supply to the second substrate 162, according to the on/off-state of the knob. The state of the inspection switch 199 is switched to the off-state, thereby shutting off the power supply to the second substrate 162, and thus enabling the second substrate 162 to be safely removed. It should be noted that when the second substrate 162 is replaced by a new one, the inspection substrate 163 may be removed from the former second substrate 162 and is attached to the new second substrate 162, whereby this inspection substrate 163 can still be continuously used.

FIG. 5 is a perspective view illustrating the first substrate 161 and the second substrate 162 of the active noise canceller 140 according to Embodiment 1. It should be noted that FIG. 5 illustrates the state of the active noise canceller 140 at the time of attaching the second substrate 162 to the first substrate 161. As illustrated in FIG. 5, the connector 171b on the first substrate 161 is connected to the connector 171a on the second substrate 162. As a result, the detection coil 141 on the first substrate 161 is connected to the wire 184 connected to the high-pass filter 151a on the second substrate 162, and a noise signal detected by the detection coil 141 is supplied to the high-pass filter 151a. Furthermore, the connector 172b on the first substrate 161 is connected to the connector 172a on the second substrate 162. As a result, the injection coil 142 on the first substrate 161 is connected to the wire 185 connected to the amplifier circuit 151b on the second substrate 162, and a noise cancelling signal produced by the amplifier circuit 151b is supplied to the injection coil 142. The first substrate 161 and the second substrate 162 are three-dimensional substrates which are provided substantially perpendicular to each other.

The controller 170 controls general operation of the power converter 100. Particularly, based on a failure signal received from the noise reduction circuit 151, the controller 170 changes an operating output of the air-conditioning apparatus 1 in such a manner as to reduce the amount of noise that leaks from the second substrate 162 to the power wires 181, 182, and 183. The operating output of the air-conditioning apparatus 1 is changed by control of the inverter 130 that is performed to increase or decrease the operating frequency of the motor 300. When receiving a failure signal from the noise reduction circuit 151, the controller 170 transmits a notification signal to notify an external controller 12 for the air-conditioning apparatus 1 that a failure occurs in the ANC 140. The external controller 12 is, for example, a remote control or a centralized controller. The external controller 12 receives an input from the user with respect to the operation of the air-conditioning apparatus 1, and displays the operating state of the air-conditioning apparatus 1. The external controller 12 includes a display, a speaker, or other devices, which visually or auditorily notifies the user that a failure occurs in the ANC 140. When receiving a failure signal from the noise reduction circuit 151, the controller 170 transmits the notification signal to the inspection LED 198, and causes the inspection LED 198 to light or flash in such a manner as to indicate the failure in the ANC 140.

Each of functions of the controller 170 is fulfilled by a processing circuit. The processing circuit is dedicated hardware or a processor. As the dedicated hardware, for example, an application specific integrated circuit (ASIC) and a field programmable gate array (FPGA) can be used. The processor executes a program stored in a storage module (not illustrated). The storage module is a memory. The memory is, for example, a volatile or nonvolatile semiconductor memory, such as a random access memory (RAM), a read only memory (ROM), a flash memory, or an erasable programmable ROM (EPROM), or a disk, such as a magnetic disk, a flexible disk, or an optical disk.

It will be described in detail how the controller 170 is operated based on the failure signal described above. Specifically, when the controller 170 receives the failure signal, in the case where IH constraint energization and a boost switching operation in a normal operating mode are performed, the controller 170 stops the IH constraint energization and the boost switching operation because they increase switching noise. As a result, the monitoring value measured by the failure detection circuit 153 is reduced. It should be noted that when the amount of boosting of the voltage by the booster circuit in the converter 120 is larger than 0, the controller 170 determines that the boost switching operation is being performed. Furthermore, the controller 170 performs a control to decrease the operating frequency, until the monitoring value measured by the failure detection circuit 153 becomes smaller than or equal to a threshold set in advance, and reduces the operating output of the air-conditioning apparatus 1. That is, from the time at which the controller 170 initially receives a failure signal to the time at which repetition of reception of the failure signal ends, the controller 170 controls the IH constraint energization to be stopped or controls the boost switching operation that is performed in normal operating mode to be stopped, or controls the operating frequency to be decreased. After initially receiving the failure signal, the controller 170 continuously notifies the external controller 12 of the failure until the worker or other persons carry out a repair or other work on the ANC 140. The controller 170 causes the inspection LED 198 to continuously light or flash to indicate occurrence of the failure in the ANC 140.

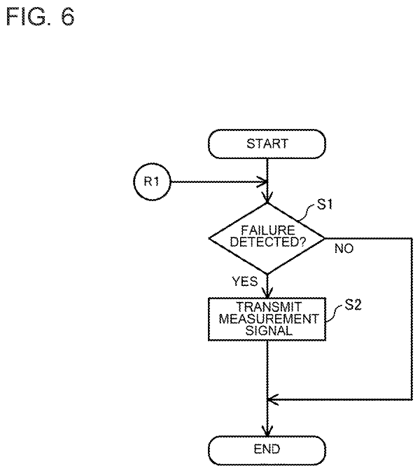

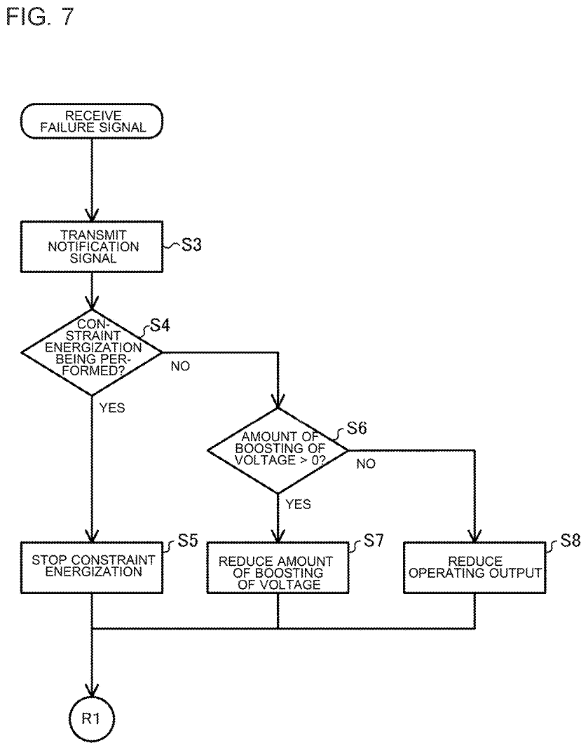

FIG. 6 is a flowchart illustrating operation of the failure detection circuit 153 according to Embodiment 1. FIG. 7 is a flowchart illustrating operation of the controller 170 according to Embodiment 1 at the time of detecting a failure. As illustrated in FIG. 6, first, the failure detection circuit 153 determines whether a failure occurs in the ANC 140 or not based on the monitoring value (S1). When determining that a failure does not occur (NO in S1), the failure detection circuit 153 ends the processing. When determining that a failure occurs (YES in S1), the failure detection circuit 153 transmits a failure signal to the controller 170 (S2). The failure detection circuit 153 performs the operation of S1 periodically.

Referring to FIG. 7, after receiving the failure signal, the controller 170 transmits a notification signal to the external controller 12 and the inspection LED 198 to notify them that a failure occurs in the ANC 140 (S3). Next, the controller 170 determines whether IH constraint energization is carried out or not (S4). When determining that the IH constraint energization is carried out (YES in S4), the controller 170 stops the IH constraint energization (S5). When determining that the IH constraint energization is not carried out (NO in S4), the controller 170 determines whether the amount of boosting of the voltage is larger than 0 or not (S6).

When determining that the amount of boosting of the voltage is larger than 0 (YES in S6), the controller 170 decreases the amount of boosting of the voltage or stops boosting of the voltage (S7). When determining that the amount of boosting of the voltage is smaller than or equal to 0 (NO in S6), the controller 170 decreases the operating output of the air-conditioning apparatus 1 (S8).

After the controller 170 stops the IH constraint energization (S5), decreases the amount of boosting of the voltage (S7), or decreases the operating output (S8), the failure detection circuit 153 re-determines whether a failure occurs in the ANC 140 or not based on the monitoring value (S1). From the time at which the controller 170 initially receives a failure signal to the time at which repetition of reception of the failure signal ends, the controller 170 repeats the above processing.

In general, devices included in the light electric circuit 62, such as an operational amplifier and a transistor, are easily affected by, for example, surge, heat, or static electricity, and there is thus a high risk that they may cause a failure. For example, there is a possibility that the devices of the light electric circuit 62 may cause a failure due to abnormal heat generation caused by an increase in current value, static electricity generated during maintenance work, or cracking caused by solder separation due to aging degradation. In contrast, devices included in the strong electric circuit 61, such as the coil 142d and a capacitor, have higher tolerance to the above factors than the devices included in the light electric circuit 62, and thus do not easily cause a failure.

In the power converter 100 according to Embodiment 1, even when replacement work is done on the light electric circuit 62 in which a failure may occurs with a high risk, it suffices that only the second substrate 162 is replaced by a new one. It is therefore possible to do the replacement work without stopping operation of an apparatus to which the ANC 140 is attached, such as the air-conditioning apparatus 1. In such a manner as described above, in the power converter 100 in Embodiment 1, it is possible to improve the serviceability of the device including the power converter 100 at the time of repairing the ANC 140.

In general, in the ANC 140, the detection coil 141 and the injection coil 142 are relatively expensive, as compared with the other components of the ANC 140. In view of this point, according to Embodiment 1, even when the second substrate 162 is replaced by a new one, it is unnecessary to replace the first substrate 161 on which the detection coil 141 and the injection coil 142 are mounted, by a new one. Accordingly, the service cost is reduced.

Even in the case where the first substrate 161 is designed in accordance with the kind of each of a plurality of devices, it is also possible to reduce the manufacturing cost. This is because the second substrate 162, which may cause a failure with a high risk and be frequently required to be replaced by a new one, can be made such that it can be used in common in the plurality of kinds of devices.

Furthermore, in Embodiment 1, the failure detection circuit 153 can detect a failure in the ANC 140 that is caused by the second substrate 162. It is therefore possible to prompt the worker to immediately repair or replace the ANC 140 in which a failure occurs, by a new one, or do another work. Accordingly, it is possible to reduce the likelihood of occurrence of failures in other devices or malfunctions of the other devices that are caused by outflow of noise, or reduce the risk of occurrence of an accident caused by these failures and malfunctions.

In general, when a failure occurs in the second substrate 162, the noise cancel operation of the ANC 140 cannot be performed, and as a result, the noise is increased. In Embodiment 1, the controller 170 controls operation of the air-conditioning apparatus 1 such that the amount of noise outflow is decreased, based on the operating state of the air-conditioning apparatus 1. Because of this control, it is possible to maintain a state in which the amount of noise outflow is reduced until the ANC 140 is repaired or replaced by a new one, and thus possible to ensure that other devices are not easily adversely affected by noise.

In addition, in Embodiment 1, the first substrate 161 and the second substrate 162 are connected substantially perpendicular to each other. Because of this configuration, a space occupied by the ANC 140 is small, as compared with that, for example, in the case where the first substrate 161 and the second substrate 162 are connected to each other substantially horizontally. For installation of the ANC 140, an additional space is not required. Therefore, it is also possible to apply the power converter 100 or the ANC 140 in Embodiment 1 to an existing air-conditioning apparatus 1 not provided with the ANC 140.

### Embodiment 2

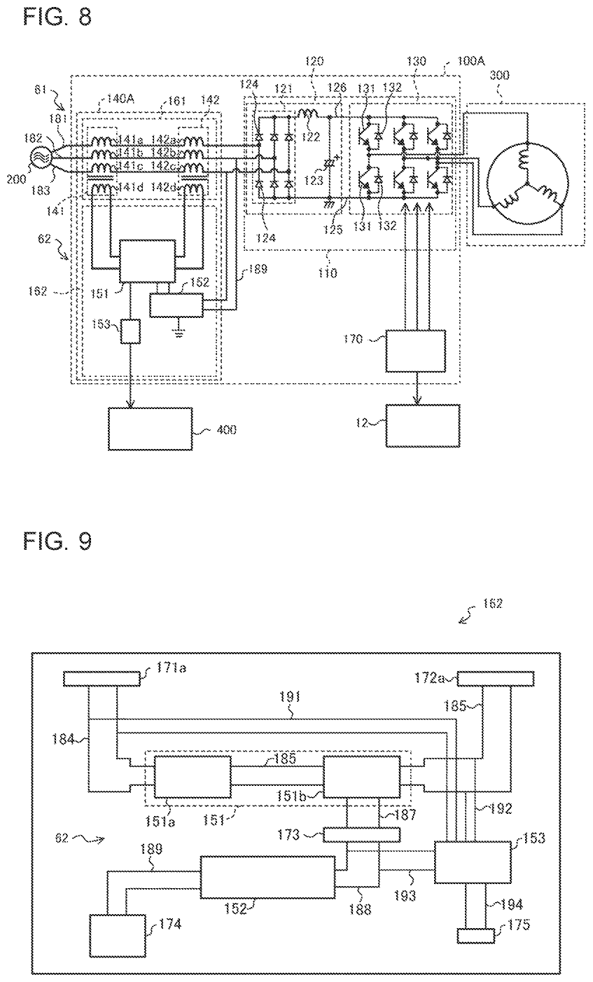

FIG. 8 is a circuit diagram illustrating a power converter 100A according to Embodiment 2. As illustrated in FIG. 8, in Embodiment 2, an ANC 140A in the power converter 100A allows an external inspection device 400 to be connected to the ANC 140A. In this regard, Embodiment 2 is different from Embodiment 1. Regarding Embodiment 2, components that are the same as those in Embodiment 1 will be denoted by the same reference signs, and their descriptions will thus be omitted. The following description is made by referring mainly to the differences between the differences between Embodiments 1 and 2.

FIG. 9 is a circuit diagram illustrating the second substrate 162 of the power converter 100A according to Embodiment 2. The external inspection device 400 is attached at the time of inspecting the ANC 140A, and configured to inspect whether a failure occurs in the ANC 140A or not. The external inspection device 400 determines whether a failure occurs in the ANC 140A or not based on the monitoring value measured by the failure detection circuit 153. Since a specific determination method is the same as the determination method for use in the failure detection circuit 153 in Embodiment 1 which determines whether a failure or not, its descriptions will thus be omitted. The external inspection device 400 includes a display, a speaker, or other devices configured to visually or auditorily notify the user of the result of the determination or other information. At the time of performing inspection, the external inspection device 400 is connected to the second substrate 162 which is provided as illustrated in FIG. 9 through a connector 175 provided on the second substrate 162. The connector 175 is connected to the failure detection circuit 153 by a wire 194.

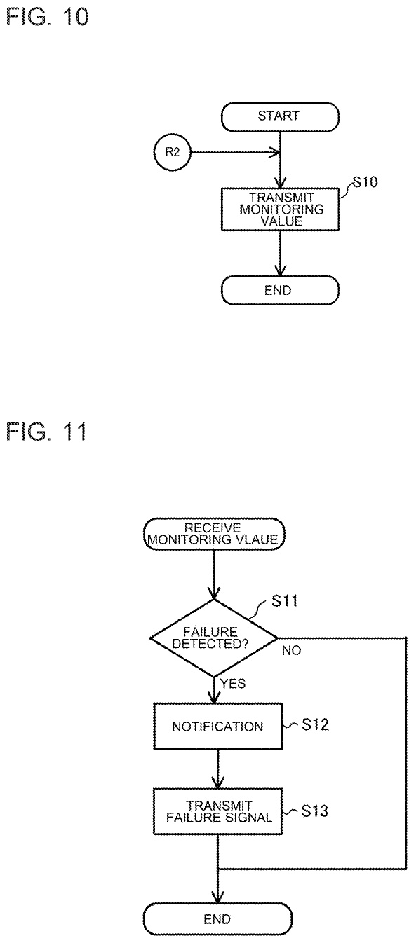

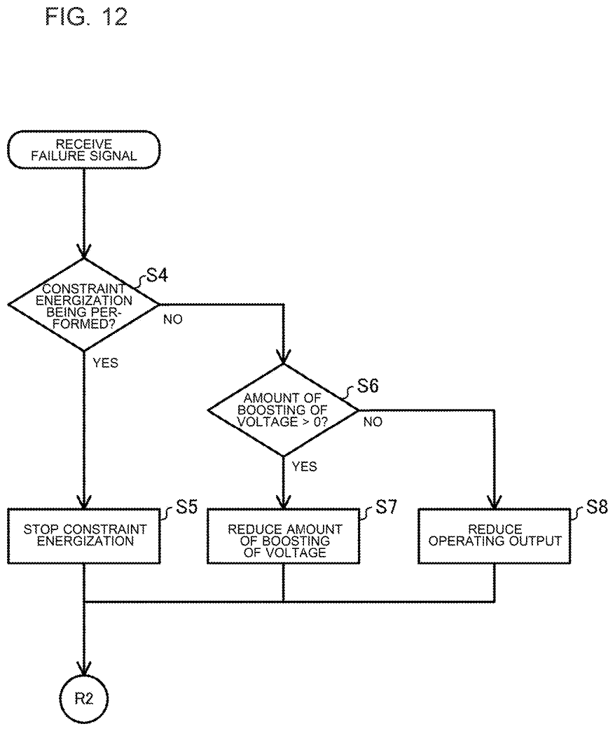

FIG. 10 is a flowchart illustrating operation of the failure detection circuit 153 according to Embodiment 2. FIG. 11 is a flowchart illustrating operation of the external inspection device 400 according to Embodiment 2. FIG. 12 is a flowchart illustrating operation of the controller 170 according to Embodiment 2 at the time of detecting a failure. First, as illustrated in FIG. 10, when the external inspection device 400 is connected to the connector 175, the failure detection circuit 153 transmits the monitoring value to the external inspection device 400 (S10). Referring to FIG. 11, the external inspection device 400 determines whether a failure occurs in the ANC 140A or not based on the monitoring value (S11). When determining that a failure does not occur (NO in S11), the failure detection circuit 153 ends the processing.

When it is determined that a failure occurs (YES in S11), the external inspection device 400 makes a notification indicating that a failure occurs in the ANC 140A (S12). Next, the external inspection device 400 transmits a failure signal to the controller 170 (S13). Referring to FIG. 12, the processes S4 to S8 that are performed after the controller 170 receives the failure signal are the same as the processes S4 to S8 in the failure detecting operation described regarding Embodiment 1, and their descriptions will thus be omitted.

According to Embodiment 2, the ANC 140A in the power converter 100A can be inspected by the external inspection device 400. Thus, even when, for example, a program for detection of a failure in the ANC 140A needs to be updated, it is also unnecessary to do any work on the failure detection circuit 153 in the ANC 140 in the power converter 100A. That is, according to Embodiment 2, in the inspection work, the worker has only to manage the external inspection device 400, and can thus accurately and easily perform the inspection work.

### Embodiment 3

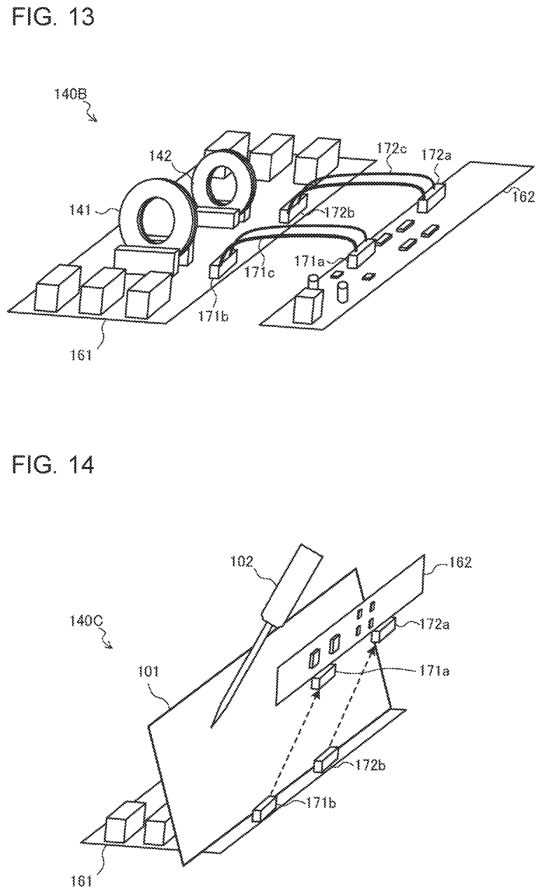

FIG. 13 is a perspective view illustrating an active noise canceller 140B according to Embodiment 3. As illustrated in FIG. 13, in Embodiment 3, in the ANC 140B, the first substrate 161 and the second substrate 162 are connected by leads 171c and 172c. In this regard, Embodiment 3 is different from Embodiment 1. Regarding Embodiment 3, components that are the same as those in Embodiment 1 will be denoted by the same reference signs, and their descriptions will thus be omitted. The following description is made by referring mainly to the differences between Embodiments 1 and 3.

As illustrated in FIG. 13, the first substrate 161 and the second substrate 162 are connected by the leads 171c and 172c. The connector 171b provided on the first substrate 161 and the connector 171a provided on the second substrate 162 are attached to respective ends of the lead 171c on both sides thereof. The connector 172b provided on the first substrate 161 and the connector 171a provided on the second substrate 162 are attached to respective ends of the lead 172c on both sides thereof. For example, the first substrate 161 and the second substrate 162 are provided substantially horizontally. The ANC 140 in Embodiment 3 also has the same function as that of the ANC 140 in Embodiment 1. It should be noted that although FIG. 13 shows that between each pair of connectors, associated two leads are connected, only one of the leads is denoted by a reference sign, descriptions concerning the other end will be omitted.

According to Embodiment 3, the first substrate 161 and the second substrate 162 are connected by the leads 171c and 172c. It is therefore possible to improve the flexibility in positioning of the first substrate 161 and the second substrate 162. It should be noted that in order to prevent noise from being picked up, it is appropriate that the leads 171c and 172c are attached without crossing each other, such that the first substrate 161 and the second substrate 162 are provided close to each other, that is, the distance between the first substrate 161 and the second substrate 162 is not too great.

According to Embodiment 3, the first substrate 161 and the second substrate 162 are connected substantially horizontally. Thus, heat generated at the detection coil 141 and the injection coil 142 on the first substrate 161 does not easily affect the components of the light electric circuit 62 on the second substrate 162. In addition, it is possible to reduce the effect of noise from the first substrate 161 on the second substrate 162.

### Embodiment 4

FIG. 14 is a perspective view illustrating an active noise canceller 140C according to Embodiment 4. As illustrated in FIG. 14, the ANC 140C of Embodiment 4 includes an insulating film 101 provided between the first substrate 161 and the second substrate 162. In this regard, Embodiment 4 is different from Embodiment 1. It should be noted that FIG. 14 illustrates removal of the second substrate 162 from the first substrate 161. Regarding Embodiment 4, components that are the same as those in Embodiment 1 will be denoted by the same reference signs, and their descriptions will thus be omitted. The following description concerning Embodiment 4 is made by referring mainly to the differences between Embodiments 1 and 4.

The insulating film 101 is made of an insulating material. The insulating film 101 is provided substantially perpendicular to the first substrate 161. The insulating film 101 is provided upright such that an edge portion of the insulating film 101 is in contact with the first substrate 161. The edge portion of the insulating film 101 is located between the connector 171a, the connector 171b, and another component on the first substrate 161.

It should be noted that in the case where the insulating film 101 has a strength enough to stand on its own lower side, it suffices that one end of the edge portion is attached to the first substrate 161. In contrast, in the case where the insulating film 101 does not have a strength enough to stand on its own lower side, it suffices that one end of the edge portion is attached to the first substrate 161, and the other end of the edge portion is attached to a surface of the electrical component box 19 that is not removed during maintenance. It is not indispensable that the insulating film 101 is attached to the ANC 140 as its accessory; that is, the insulating film 101 may be prepared for the maintenance and used by the worker. In this case, it is preferable that a guide for provision of the insulating film 101 be provided in advance at the first substrate 161 in order that a maintenance worker could easily provide the insulating film 101.

According to Embodiment 4, the active noise canceller 140C includes the insulating film 101 provided between the first substrate 161 and the second substrate 162. Thus, at the time of replacing of the second substrate 162 by a new one, the insulating film 101 can prevent a worker's body or a conductor 102, such as a tool, from touching the first substrate 161.

Although the above descriptions are the descriptions concerning the embodiments, the power converter 100 and the air-conditioning apparatus 1 according to the present disclosure can be modified as appropriate within the gist of the present disclosure. For example, the control power circuit 152 may be provided at a location other than on the second substrate 162. The second substrate 162 may be provided with an arrestor, a varistor, a Zener diode, etc., which are configured to protect the noise reduction circuit 151. It should be noted that the arrestor, the varistor, the Zener diode, etc., are also included in the light electric circuit 62.

As described regarding Embodiment 1, in the case where the first substrate 161 and the second substrate 162 are provided as three-dimensional substrates such that the second substrate 162 is located substantially perpendicular to the first substrate 161, it is preferable that components be mounted on the both sides of the second substrate 162 in the following manner. That is, it is preferable that passive components such as connectors, a resistance, and a capacitor be mounted on one of the both sides of the second substrate 162 that faces the detection coil 141 and the injection coil 142 or the capacitor on the first substrate 161; and active components such as an operational amplifier, a transistor, and a chip IC be mounted on the other side of the second substrate 162, which faces in the opposite direction to the direction in which the above one side faces the detection coil 141 and the injection coil 142 or the capacitor on the first substrate 161. That is, the active components of the light electric circuit 62 are mounted on a side of the second substrate 162 which is opposite to a side thereof facing the detection coil 141 and the injection coil 142 or the capacitor mounted on the first substrate 161. Because of the above configuration, the active components on the second substrate 162 do not easily receive heat from the detection coil 141, the injection coil 142, and other components on the first substrate 161. The area of a ground pattern provided on the both sides of the second substrate 162 may be changed. For example, it is preferable that as compared with one side of the second substrate 162 that faces the detection coil 141 and the injection coil 142 on the first substrate 161, the area of the ground pattern be made large on the other side of the second substrate 162 which faces in the opposite direction to the direction in which the above one side of the second substrate 162 faces the detection coil 141 and the injection coil 142 on the first substrate 161. Thus, it is possible to reduce the effect of noise made from the strong electric circuit 61 on the other side of the second substrate 162, which faces in the opposite direction to the direction in which the above one side faces the detection coil 141 and the injection coil 142 on the first substrate 161. Conversely, the area of the ground pattern may be made large on the one side of the second substrate 162, which faces the detection coil 141 and the injection coil 142 on the first substrate 161, as compared with the other side of the second substrate 162, which faces in the direction in which the above one side faces the detection coil 141 and the injection coil 142 on the first substrate 161. Because of this configuration, it is possible to improve heat dissipation performance on the one side of the second substrate 162, which faces toward the detection coil 141 and the injection coil 142 on the first substrate 161. It should be noted that it is not indispensable that components are mounted on the both sides of the second substrate 162 in the above manner.

The failure detection circuit 153 may be configured to simply detect only whether a failure occurs in the ANC 140 or not. In this case, the failure detection circuit 153 does not need to measure a change in the monitoring value that is made by a change in the operating condition of the air-conditioning apparatus 1, after detecting a failure in the ANC 140. Also, in this case, when the failure detection circuit 153 detects the failure in the ANC 140, the controller 170 stops the operation of the air-conditioning apparatus 1.

A zero-phase current transformer (ZCT) or other devices may be provided at the power wires 181, 182, and 183 to directly detect a common-mode current, thereby to detect the amount of noise. Furthermore, the failure detection circuit 153 or the external inspection device 400 may be configured to detect whether a failure occurs in the ANC 140 or not based on the amount of noise which is detected by this method.

AI related to machine learning may be applied to a failure detection algorithm for use in the failure detection circuit 153 or the external inspection device 400. As a specific method, for example, a monitoring value and other data in normal operating mode are learned in advance, and are stored in the controller 170 or the external inspection device 400. The failure detection circuit 153 or the external inspection device 400 compares the learned monitoring value and the monitoring values measured during the inspection with each other. When determining that the monitoring value measured during the inspection deviates from the learned monitoring value in the normal operating mode, the failure detection circuit 153 or the external inspection device 400 determines that a failure occurs in the ANC 140. The monitoring value and other data may be learned in accordance with the kind of an abnormality such as short circuit, circuit opening, or oscillation. Furthermore, the monitoring value and other data may be learned in association with a sign that appears before an actual occurrence of a failure.

In Embodiment 1, the external controller 12 and the inspection LED 198 are made to make a notification indicating that a failure occurs in the ANC 140. However, one of the external controller 12 and the inspection LED 198 may be made to make a notification indicating that a failure occurs in the ANC 140. In Embodiment 2 also, occurrence of a failure in the ANC 140 may be indicated not only by the notification made by the external inspection device 400, but also by the notification made by the inspection LED 198.

In Embodiment 2, the connector 175 for connection of the external inspection device 400 may be provided on a surface of the electrical component box 196, not on the second substrate 162.

Regarding the above description concerning each of the embodiments is made with respect to the case where the power converter 100 is applied to the air-conditioning apparatus 1. However, the power converter 100 is also applicable to a refrigeration cycle apparatus other than the air-conditioning apparatus 1, or to another apparatus that includes a component that is driven by the motor 300. Furthermore, the power converter 100 may also be applied to an apparatus, such as an electromagnetic cooker, which does not include a motor, but has a load that is operated by power supplied from a power supply through a power wire.

### REFERENCE SIGNS LIST

1: air-conditioning apparatus, 2: outdoor unit, 3: indoor unit, 4: compressor, 5: four-way valve, 6: outdoor heat exchanger, 7: outdoor fan, 8: expansion valve, 9: indoor heat exchanger, 10: indoor fan, 11: refrigerant pipe, 12: external controller, 61: strong electric circuit, 62: light electric circuit, 100: power converter, 100A: power converter, 101: insulating film, 102: conductor, 110: power conversion module, 120: converter, 121: rectifier circuit, 122: DC reactor, 123: smoothing capacitor, 124: rectifier diode, 125: positive bus-bar, 126: negative bus-bar, 130: inverter, 131: semiconductor switch, 132: freewheeling diode, 140: active noise canceller, 140A: active noise canceller, 140B: active noise canceller, 140C: active noise canceller, 141: detection coil, 141a: coil, 141b: coil, 141c: coil, 141d: coil, 142: injection coil, 142a: coil, 142b: coil, 142c: coil, 142d: coil, 151: noise reduction circuit, 151a: high-pass filter, 151b: amplifier circuit, 152: control power circuit, 153: failure detection circuit, 161: first substrate, 162: second substrate, 163: inspection substrate, 170: controller, 171a: connector, 171b: connector, 171c: lead, 172a: connector, 172b: connector, 172c: lead, 173: connector, 174: connector, 175: connector, 181: power wire, 182: power wire, 183: power wire, 184: wire, 185: wire, 186: wire, 187: wire, 188: wire, 189: wire, 191: wire, 192: wire, 193: wire, 194: wire, 195: power wire, 196: electrical component box, 197: lead, 198: inspection LED, 199: inspection switch, 200: AC power supply, 300: motor, 400: external inspection device

1. A power converter comprising:
a power conversion module configured to convert a voltage and a frequency of power that is supplied from a power supply through a power wire, and to supply to a load, power having a voltage and a frequency that are obtained by conversion; and
an active noise canceller configured to detect noise that flows through the power wire, and to output a noise canceling signal that attenuates the noise to the power wire,
wherein
the active noise canceller includes
a first substrate on which a strong electric circuit configured to detect the noise is mounted, and
a second substrate on which a light electric circuit configured to produce the noise canceling signal is mounted.

2. The power converter of claim 1, wherein
the power conversion module includes
a converter configured to rectify a voltage that is applied from the power supply, and
the active noise canceller is connected between the power supply and the converter.

3. The power converter of claim 1, wherein the strong electric circuit includes a coil connected to the power wire or a capacitor connected to the power wire.

4. The power converter of claim 3, wherein
the first substrate and the second substrate are three-dimensional substrates that are provided such that the second substrate is substantially perpendicular to the first substrate, and
an active component of the light electric circuit is mounted on a surface of the second substrate which is opposite to a side of the second substrate that faces the coil or the capacitor mounted on the first substrate.

5. The power converter of claim 1, wherein the light electric circuit includes an operational amplifier or a transistor.

6. The power converter of claim 1, wherein the first substrate and the second substrate are electrically connected by a wire or a connector.

7. The power converter of claim 1, further comprising an insulating film provided between the first substrate and the second substrate.

8. The power converter of claim 1, wherein the light electric circuit includes a noise reduction circuit configured to produce the noise canceling signal by processing, as an input, a noise signal that is induced in the strong electric circuit by common-mode noise that flows from the power supply to the power conversion module, and to output the produced noise canceling signal to the strong electric circuit.

9. The power converter of claim 8, wherein the light electric circuit includes a failure detection circuit configured to detect a failure in the active noise canceller based on a monitoring value indicating a value of a current or a voltage that is obtained from the noise signal or the noise canceling signal.

10. A refrigeration cycle apparatus comprising:
the power converter of claim 1;
a compressor configured to be driven by a motor that is the load;
a condenser configured to condense refrigerant discharged from the compressor;
an expansion valve configured to reduce a pressure of the condensed refrigerant; and
an evaporator configured to evaporate the refrigerant whose pressure is reduced.

11. The refrigeration cycle apparatus of claim 10, further comprising an external controller configured to display an operation state of a refrigeration cycle apparatus,
wherein
the power converter further includes a controller,
the light electric circuit includes
a noise reduction circuit configured to produce the noise canceling signal by processing, as an input, a noise signal that is induced in the strong electric circuit by common-mode noise that flows from the power supply to the power conversion module, and to output the produced noise canceling signal to the strong electric circuit, and
a failure detection circuit configured to detect a failure in the active noise canceller based on a monitoring value indicating a value of a current or a voltage that is calculated from the noise signal or the noise canceling signal,
the failure detection circuit is configured to transmit a failure signal to the controller when a failure occurs in the active noise canceller, and
the controller is configured to cause, when receiving the failure signal, the external controller to make a notification indicating that a failure occurs in the active noise canceller.
